(19) United States
(12) Patent Application Publication
(10) Pub. No.: US 2007/0026665 A1
(43) Pub. Date: Feb. 1, 2007

(54) METHOD OF FABRICATING A DUAL DAMASCENE INTERCONNECT STRUCTURE

(75) Inventors: Kallol Bera, San Jose, CA (US); Gerardo A. Delgadino, Santa Clara, CA (US); Allen Zhao, Mountain View, CA (US); Yan Ye, Saratoga, CA (US)

Correspondence Address: MOSER IP LAW GROUP / APPLIED MATERIALS, INC., 1040 BROAD STREET, 2ND FLOOR, SHREWSBURY, NJ, 07702, US

(73) Assignee: Applied Materials, Inc., Santa Clara, CA (US)

(21) Appl. No.: 11/535,935

(22) Filed: Sep. 27, 2006

Related U.S. Application Data
(63) Continuation of application No. 10/663,304, filed on Sep. 16, 2003.

(51) Int. Cl. H01L 21/4763; H01L 21/461; H01L 21/302

(52) U.S. Cl. 438/623; 438/627; 438/633; 438/638; 438/692; 438/735; 438/738; 257/E21.252

(57) ABSTRACT

A method of fabricating a dual damascene interconnect structure uses a very high frequency high-density plasma and selectively controlled substrate bias for in-situ etching a trench above a via hole of the interconnect structure and a barrier layer between the via hole and underlying conductive layer.

### CROSS-REFERENCE TO RELATED APPLICATIONS

This application is a continuation of co-pending U.S. patent application Ser. No. 10/663,304, filed Sep. 16, 2003, which is herein incorporated by reference.

### BACKGROUND OF THE INVENTION

1. Field of the Invention

The present invention generally relates to the fabrication of semiconductor integrated circuits. More specifically, the present invention relates to a method of fabricating interconnect structures in a semiconductor substrate processing system.

2. Description of the Related Art

Integrated circuits (IC) are manufactured by forming discrete semiconductor devices on a surface of a semiconductor substrate, such as a silicon (Si) wafer. A multi-level network of interconnect structures is then formed to interconnect the devices. Copper (Cu) is the material of choice for interconnect structures of advanced IC devices having high circuit density. In addition to superior electrical conductivity, copper is more resistant than aluminum (Al) to electromigration, a phenomenon that may destroy a thin film conductive line during IC operation.

In the semiconductor industry, much effort is spent in developing smaller IC devices with ever-increasing operating speeds. To increase the circuit density, a dual damascene technique may be used during fabrication of the IC devices. To increase the operating speed of such a device, inter-metal dielectric (IMD) layers are formed using materials having dielectric constants less than 4.0. Such materials are generally referred to as low-k materials. The low-k materials generally comprise carbon-doped dielectrics, such as organic doped silicon glass (OSG), fluorine doped silicon glass (FSG), organic polymers, and the like.

An IC device comprises a plurality of interconnect structures that are separated from each other and the substrate by the IMD layers. Such structures are generally fabricated using a dual damascene technique that comprises forming an insulator layer (e.g., IMD layer) into which trenches and openings are etched to pattern the conductive lines and contact holes, or vias. The copper is then used to fill (metallize) the trenches and openings in the IMD layer forming the conductive lines and vias, respectively. During the copper metallization process, an excess amount of copper may be deposited onto the substrate. The excess metal may be removed using a planarization process, e.g., chemical-mechanical polishing (CMP) process. After the planarization process, the interconnect structure is embedded in the IMD layer coplanar with an exposed surface of the layer, such that the next wiring layer may be formed on top of the embedded IMD layer.

During fabrication of the interconnect structure, etch processes (e.g., reactive ion etch (RIE), inductively coupled plasma (ICP) etch, and the like) are generally used to form the openings and trenches in the low-k IMD layer. These etch processes may form defects that degrade the interconnect structure. The etch-related defects commonly include faceting, micro-trenching, critical dimensions (CD) bias, micro-loading, striations, and sloped sidewalls. The terms “faceting” and “micro-trenching” are used herein to refer to the undesirable overetching of an edge of the via hole and a corner region of the trench, and the terms “critical dimensions (CD) bias” relates to a difference between critical dimensions of the opening or trench and their respective elements of the etch mask. Correspondingly, the term “micro-loading” refers to a difference in etch rates in the areas having different device density, while the terms “striations” and “sidewall slope” describe, respectively, surface roughness and vertical profiles of the opening or trench. Etch-related defects of the dual damascene interconnect structures may affect performance and increase costs of the integrated circuits and devices that include such structures.

Therefore, there is a need in the art for an improved method of fabricating a dual damascene interconnect structure.

### SUMMARY OF THE INVENTION

The present invention is a method of fabricating a dual damascene interconnect structure having the steps of providing a substrate having a film stack comprising sequentially formed on the substrate a first barrier layer, a conductive layer embedded in a first dielectric layer, a second barrier layer, a second dielectric layer, and a cap layer, etching a via hole in the cap layer and the second dielectric layer, filling a portion of a depth of the via hole with a masking material, etching in-situ the cap layer, a trench in the second dielectric layer, the masking material, and the second barrier layer, and metalizing the via hole and the trench. In one embodiment, the process uses a very high frequency high-density plasma and selectively controlled substrate bias. The method fabricates dual damascene interconnect structures having low faceting, micro-trenching, CD bias, and micro-loading, and striations, as well as highly vertical sidewalls.

### BRIEF DESCRIPTION OF THE DRAWINGS

The teachings of the present invention can be readily understood by considering the following detailed description in conjunction with the accompanying drawings, in which:

FIGS. 1A-1B depict a flow diagram of a method of fabricating a dual damascene interconnect structure in accordance with one embodiment of the present invention;

FIGS. 2A-2M depict a series of schematic, cross-sectional and top plan views of a substrate having a dual damascene interconnect structure being formed in accordance with the method of FIGS. 1A-1B; and

FIG. 3 depicts a schematic diagram of an exemplary plasma processing apparatus of the kind used in performing portions of the inventive method.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of fabricating a dual damascene interconnect structure on a substrate (e.g., semiconductor substrate, such as a silicon (Si) wafer, and the like) using a very high frequency (VHF) plasma source. The method uses an etch process that in-situ forms a trench above a via hole of the structure and removes a barrier layer between the via hole and underlying conductive layer. In one embodiment, the etch process uses a very high frequency (VHF) high-density plasma and a selectively controlled substrate bias. Such a process can be performed in, for example, the ENABLER™ VHF etch chamber available from Applied Materials, Incorporated, located in Santa Clara, Calif.

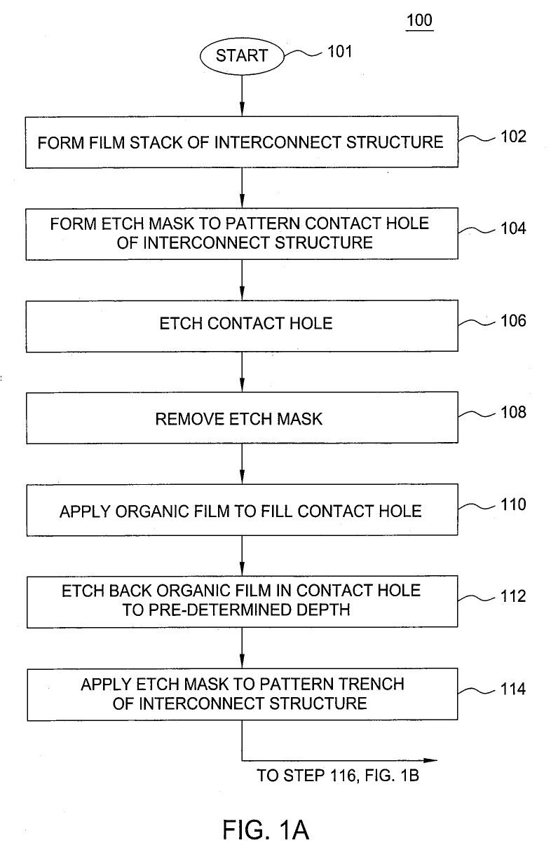

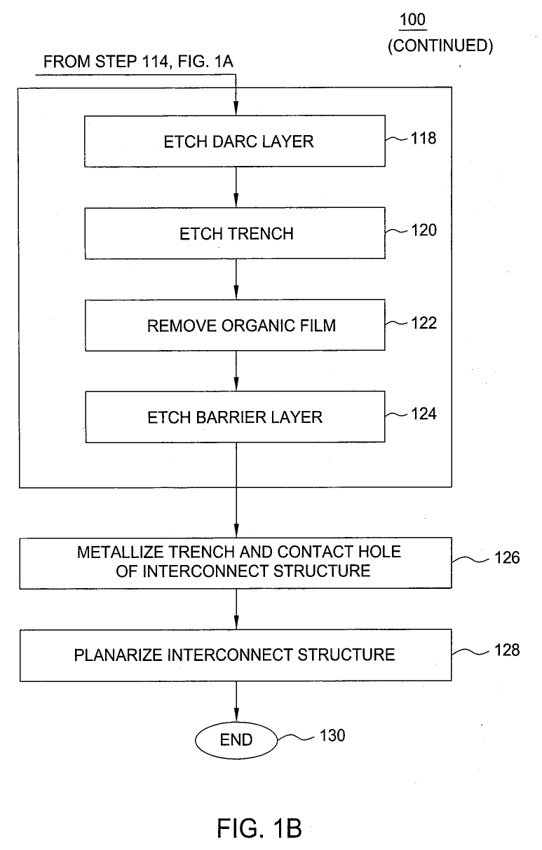

FIGS. 1A-1 B depict a flow diagram of one embodiment of the inventive method for fabricating a dual damascene interconnect structure as a sequence 100. The sequence 100 comprises the processes that are performed upon a film stack of the dual damascene interconnect structure.

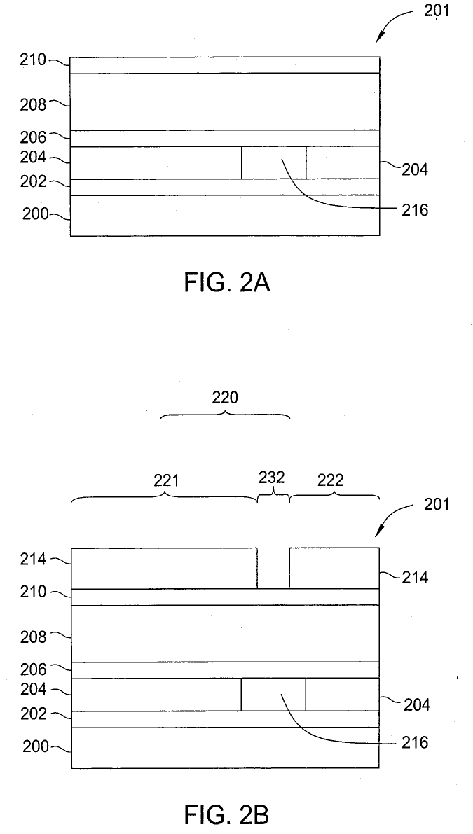

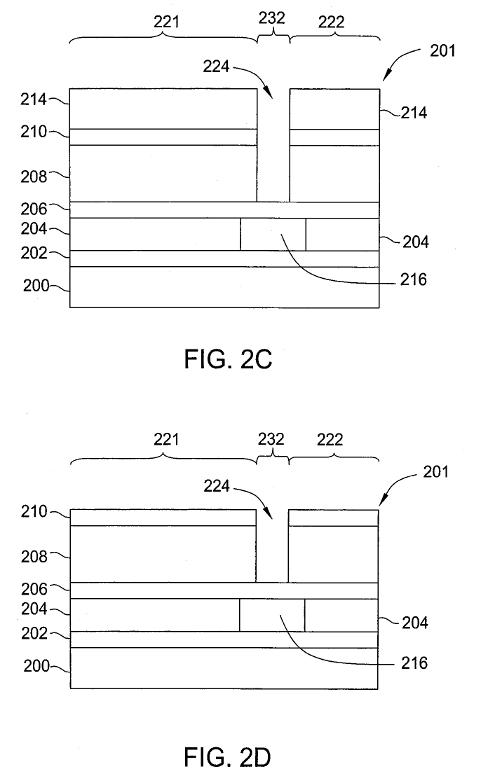

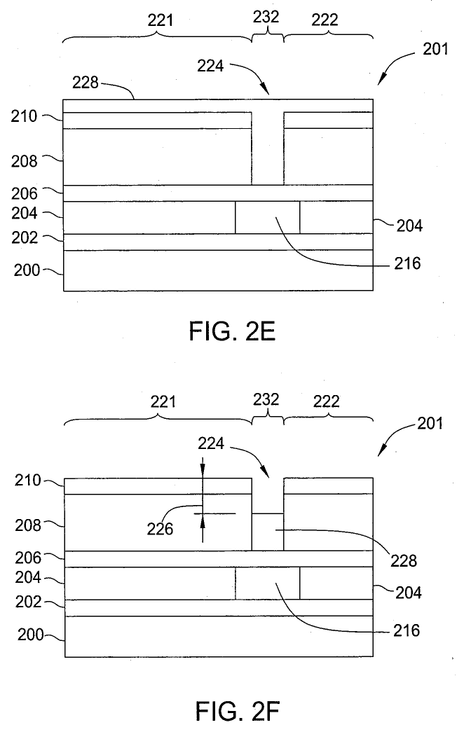

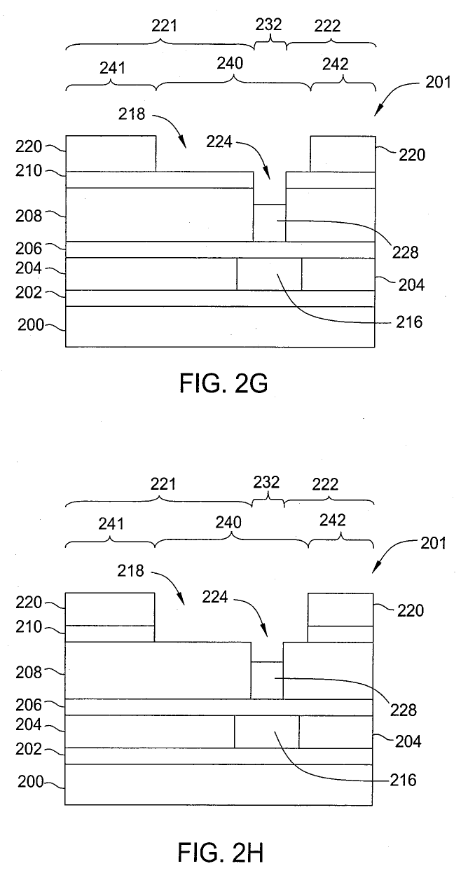

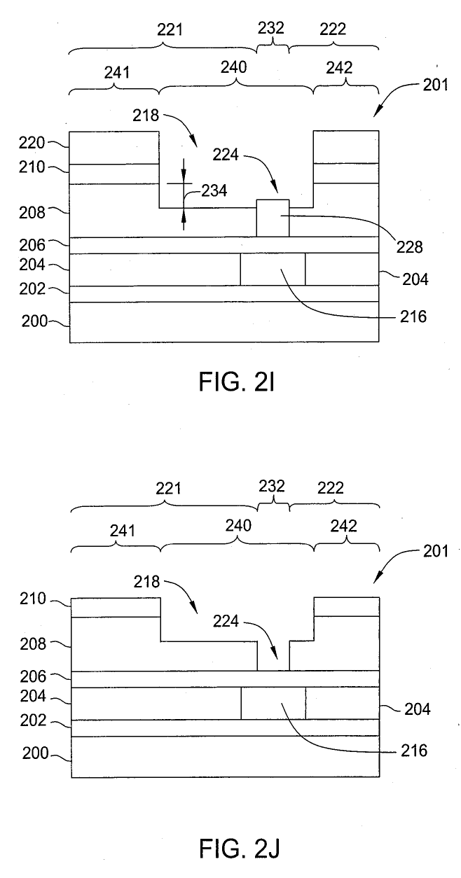

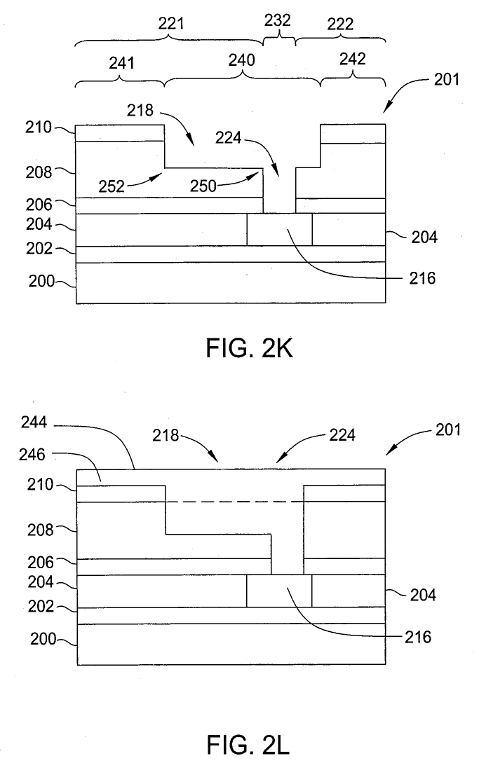

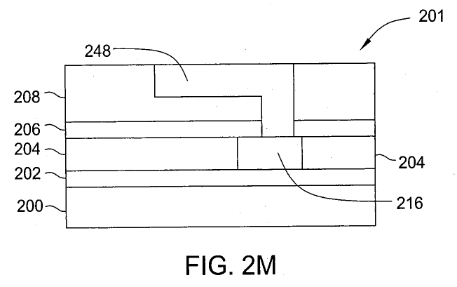

FIGS. 2A-2M depict a series of schematic, cross-sectional views of a substrate showing the interconnect structure being fabricated using the sequence 100. The cross-sectional views in FIGS. 2A-2M relate to individual processing steps of the sequence 100. The elements in FIGS. 2A-2M are not depicted to scale and are simplified for illustrative purposes.

Sub-processes and lithographic routines (e.g., exposure and development of photoresist, wafer cleaning procedures, and the like) are well known in the art and, as such, are not shown in FIGS. 1A-1B and FIGS. 2A-2M. To best understand the invention, the reader should simultaneously refer to FIGS. 1A-1 B and FIGS. 2A-2M.

The sequence 100 starts at step 101 and proceeds to step 102 when a film stack 201 of a dual damascene interconnect structure being fabricated is formed on a substrate 200 (e.g., silicon wafer) (FIG. 2A). Herein the terms “substrate” and “wafer” are used interchangeably. In one illustrative embodiment, the film stack 201 comprises a first barrier layer 202, a first dielectric layer 204 including an embedded conductive line 216, a second barrier layer 206, a second dielectric layer 208, and a cap layer 210.

The first barrier layer 202 and the second barrier layer 206 are generally formed to a thickness of about 300 to 1000 Angstroms from a dielectric material, such as silicon dioxide (SiO₂), silicon nitride (Si₃N₄), silicon carbide (SiC), and the like. Silicon carbide (SiC) materials are available from Applied Materials, Inc. of Santa Clara, Calif. under the trademarks BLOK-II™ and BLOK-III™. In one exemplary embodiment, the first barrier layer 202 and the second barrier layer 206 comprise silicon nitride (Si₃N₄) and BLOK-II™, respectively.

The first dielectric layer 204 and the second dielectric layer 208 are generally formed of materials having a dielectric constant that is less than about 4.0. Herein such materials are referred to as low-k materials. Suitable low-k materials may include carbon-doped dielectrics, such as carbon doped silicon oxide, organic doped silicon glass (OSG), fluorine doped silicon glass (FSG), and the like. Carbon doped silicon oxide such as BLACK DIAMOND™ and BLACK DIAMOND II™ are available from Applied Materials, Inc. of Santa Clara, Calif. In one exemplary embodiment, the first dielectric layer 204 and the second dielectric layer 208 are formed from carbon doped silicon oxide. The dielectric layers 204, 208 are generally formed to a thickness of about 1000 to 5000 and 2000 to 10,000 Angstroms, respectively.

The conductive line 216 may be formed from a metal (e.g., copper (Cu), aluminum (Al), tantalum (Ta), tungsten (W), titanium (Ti), and the like) or a conductive compound (e.g., tantalum nitride (TaN), titanium nitride (TiN), tungsten nitride (WN), and the like). In one exemplary embodiment, the conductive line 216 is formed from copper to a thickness of about 1000 to 5000 Angstroms.

The cap layer 210 is typically a dielectric layer formed from material that may also be used as an anti-reflective coating during patterning a mask 214 (discussed in reference to step 104 below), as well as preferably has low etch selectivity for the chemistries used to etch the low-k second dielectric layer 208. Suitable materials for the cap layer 210 include silicon oxynitride (SiOₓN_{y}), where x and y are integers, and the like. The cap layer 210 is typically formed to a thickness of about 300 to 1000 Angstroms.

Layers comprising the film stack 201 may be formed using any conventional thin film deposition technique, such as atomic layer deposition (ALD), physical vapor deposition (PVD), chemical vapor deposition (CVD), plasma enhanced CVD (PECVD), and the like. Fabrication of the dual damascene interconnect structure may be performed using the respective processing modules of CENTURA®, ENDURA®, ELECTRA®, MIRRA®, and other semiconductor wafer processing systems available from Applied Materials, Inc. of Santa Clara, Calif.

At step 104, a patterned mask 214 is formed on the cap layer 210 (FIG. 2B). The mask 214 defines the location and topographic dimensions of a via hole 224 of the dual damascene interconnect structure being formed. Specifically, the mask 214 protects regions 221 and 222 and exposes region 232 of the wafer 200. The mask 214 may be formed from photoresist using a conventional lithographic patterning process. The cap layer 210, which is also an anti-reflective coating (ARC), controls the reflection of light used to expose the photoresist during the patterning process. As feature (e.g., via hole or trench) sizes are reduced, inaccuracies in an etch mask pattern transfer process can arise from optical limitations inherent to the lithographic process, such as the light reflection. During the patterning process, the photoresist is exposed through a patterned reticle, developed, and then the undeveloped portion of the photoresist layer is removed. The remaining developed photoresist (generally, a polymer) forms the mask 214.

At step 106, the cap layer 210 and the second dielectric layer 208 are etched in the region 232 to form a via hole 224 (FIG. 2C). In one exemplary embodiment, step 106 uses a plasma etch process that includes a gas mixture comprising carbon tetrafluoride (CF₄), nitrogen (N₂), and one or more diluant gases, such as argon (Ar) or carbon monoxide (CO). Step 106 uses the mask 214 as an etch mask and the second barrier layer 206 as an etch stop layer. Step 106 may be performed, for example, using an etch chamber connected to a PRODUCER® or CENTURA® semiconductor processing system, both available from Applied Materials, Incorporated, located in Santa Clara, Calif. One such system is described in commonly assigned U.S. Pat. No. 5,855,681, issued Jan. 5, 1999, which is incorporated herein by reference.

In one exemplary embodiment, the cap layer 210 comprising silicon oxynitride and the second dielectric layer 208 comprising carbon doped silicon oxide are etched by providing carbon tetrafluoride (CF₄) at a flow rate of 20 to 150 sccm, nitrogen (N₂) at a flow rate of 40 to 300 sccm (corresponds to a CF₄:N₂ flow ratio ranging from 1:1 to 1:5), argon (Ar) at a flow rate of 0 to 2000 sccm, applying a source power to the upper electrode between 0 and 2000 W, applying a cathode bias power between 800 and 3000 W, and maintaining a wafer pedestal temperature of about 0 to 40 degrees Celsius and a chamber pressure between 10 and 100 mtorr. One illustrative process uses CF₄ at a flow rate of 100 sccm, N₂ at a flow rate of 180 sccm (i.e., a CF₄:N₂ flow ratio of about 10:18), Ar at a flow rate of 1000 sccm, applies 150 W of source power to the upper electrode, 1000 W of cathode bias power, and maintains a wafer pedestal temperature of 20 degrees Celsius and a chamber pressure of 30 mtorr. Such a process provides etch selectivity for silicon oxynitride (layer 210) and carbon doped silicon oxide (layer 208) over the photoresist (mask 214) of at least 2:1 and 3:1, respectively.

At step 108, the mask 214 is removed, or stripped (FIG. 2D). Generally, step 108 uses a photoresist stripping process that includes a plasma comprising oxygen (O₂). During step 108, the cap layer 210 may be used as an etch stop layer. Step 108 may be performed using, e.g., Advanced Strip and Passivation (ASP) module of the CENTURA® system. The ASP module is a microwave downstream plasma reactor in which the plasma is confined such that only reactive neutrals are allowed to enter the process chamber, thereby precluding plasma-related damage to the circuits formed on the substrate. One photoresist stripping process is disclosed in commonly assigned U.S. patent application Ser. No. 10/245,130, filed Sep. 16, 2002. Alternatively, step 108 can be performed using the AXIOM® module of the CENTURA® system. The AXIOM® module is a remote plasma reactor. The AXIOM® module is described in detail in U.S. patent application Ser. No. 10/264,664, filed Oct. 4, 2002, which is herein incorporated by reference. Alternatively, step 108 may be performed using an etch reactor.

At step 110, a masking material is applied to the substrate 200 (FIG. 2E). The masking material fills the via hole 224 and may form a film 228 atop the cap layer 210. The masking material is generally an organic material (e.g., polysiloxane, photoresist, and the like) having low etch selectivity to the chemistries used to etch the low-k second dielectric layer 208 and the cap layer 210. In one exemplary embodiment, the masking film 228 comprises photoresist.

At step 112, the masking material is etched back (FIG. 2F). During step 112, the film 228 is removed from the cap layer 210 and the masking material in the via hole 224 is etched to a pre-determined depth 226. The depth 226 is equal to or smaller than a depth 234 for a trench 218 (both are discussed in reference to step 116 and FIG. 21 below) of the interconnect structure being fabricated. In one exemplary embodiment, step 112 performs a plasma etch process that uses a gas mixture comprising O₂ and, optionally, N₂.

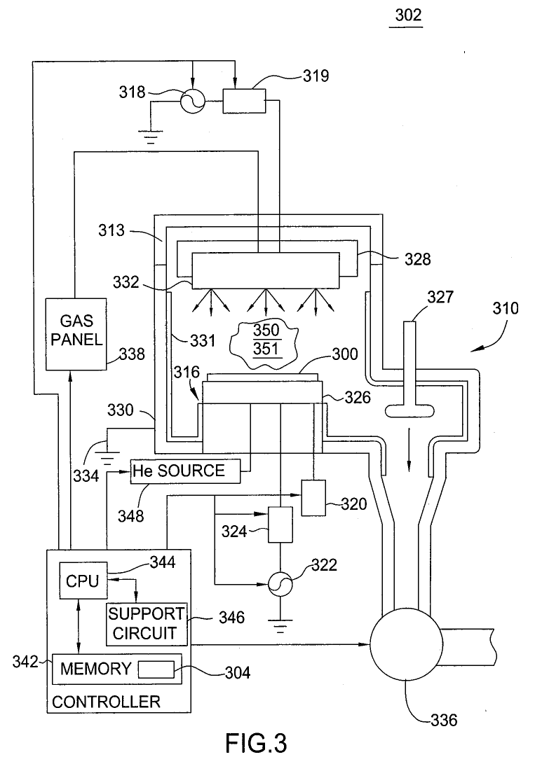

Step 112 can be performed, for example, using an etch module of the CENTURA® system. The etch module may be a dual frequency, high-density plasma etch reactor providing independent control of ion energy, plasma density and uniformity, as well as wafer temperature. In one embodiment, the reactor uses a very high frequency (VHF) plasma source (e.g., above about 100 MHz plasma source) and a 13.56 MHz source of substrate bias. The etch module is disclosed in detail in U.S. patent application Ser. No. 10/192,271, filed Jul. 9, 2002, which is herein incorporated by reference. Salient features of the etch module are briefly discussed below in reference to FIG. 3.

In one exemplary embodiment, the masking film 228 comprising organic barrier anti-reflective coating (BARC) is etched by providing oxygen (O₂) at a flow rate of 100 to 1000 sccm, applying a VHF source power between 0 and 400 W to the upper electrode, applying a cathode bias power between 100 and 400 W, and maintaining a wafer pedestal temperature between 0 and 20 degrees Celsius and a chamber pressure between 5 and 200 mTorr. One illustrative process provides O₂ at a flow rate of 400 sccm, applies 0 W of source power to the upper electrode, 400 W of cathode bias power, and maintains a wafer pedestal temperature of 10 degrees Celsius and a chamber pressure of 10 mTorr. Such a process provides etch selectivity for BARC (film 228) over silicon oxynitride (layer 210) and carbon doped silicon oxide (layer 208) of at least 50:1 and 50:1, respectively.

At step 114, a patterned mask 220 is formed on the cap layer 210 (FIG. 2G). The mask 220 defines the location and topographic dimensions of the trench 218 of the dual damascene interconnect structure being fabricated. The mask 220 may be formed using a conventional lithographic patterning process. Specifically, the mask 220 protects regions 241 and 242 and exposes region 240 of the wafer 200.

At step 116, the trench 218 is formed in the second dielectric layer 208. During step 116, the second barrier layer 206 is etched and removed in the region 232 beneath the via hole 224 (FIGS. 2H-2K). In one exemplary embodiment, step 116 uses an in-situ plasma etch process that includes a very high frequency (VHF), high-density plasma. Such plasma etch process may be performed using, for example, the ENABLER™ etch module of the CENTURA® system. The etch process provides low faceting, micro-trenching, critical dimensions (CD) bias, micro-loading, low or no striations, and forms trenches having highly vertical sidewalls. The terms “faceting” and micro-trenching herein specifically relate to the undesirable overetching of an edge 250 of the via hole 224 and a corner region 252 of the trench 218 (FIG. 2K). In the embodiment shown and described below, step 116 comprises four periods (periods 118, 120, 122, and 124), however, in alternate embodiments, processes of any two or more of such periods may be performed simultaneously.

During the period 118, the cap layer 210 (e.g., silicon oxynitride) is removed in the region 240 (FIG. 2H). The period 118 may use the photoresist mask 220 as an etch mask and the second dielectric layer 208 as an etch stop layer. In one embodiment, the period 118 may use the process described above with respect to step 106. Step 118 may use the same etching chemistry and process parameters as step 106 above, other than the ranges for a flow rate of CF₄ (30-400 sccm), cathode bias power (400-1200 W), and chamber pressure (60-150 mT). One illustrative process uses CF₄ at a flow rate of 300 sccm, 600 W of cathode bias power, and maintains a chamber pressure of 150 mTorr.

During the period 120, the second dielectric layer 208 (e.g., carbon doped silicon oxide) is etched in the region 240 to a predetermined depth 234, thereby forming the trench 218 (FIG. 21). During the period 120, the masking film 228 (e.g., photoresist) in the via hole 224 protects the hole from etching. In one exemplary embodiment, the period 120 uses a gas mixture comprising carbon tetrafluoride (CF₄), nitrogen (N₂), and an inert diluent gas, such as argon (Ar), neon (Ne), and the like. During the period 120, a flow rate of carbon tetrafluoride and the substrate bias power may be used for selective control of the micro-trenching, sidewall angle and striations, critical dimension (CD) bias, and etch rate, as well as etch selectivity for the photoresist mask 220. Other selectively controlled parameters may include a fraction of dissociation of the etchant gas mixture and a gas pressure in the process chamber.

In one illustrative embodiment, the second dielectric layer 208 comprising carbon doped silicon oxide is etched by providing carbon tetrafluoride (CF₄) at a flow rate of 100 to 500 sccm, nitrogen (N₂) at a flow rate of 30 to 120 sccm (i.e., a CF₄:N₂ flow ratio ranging from approximately 1:1.2 to 17:1), argon (Ar) at a flow rate of 100 to 600 sccm, applying a VHF source power between 1000 and 2000 W to the upper electrode, applying a cathode bias power between 800 and 1800 W, and maintaining a wafer pedestal temperature between 0 and 30 degrees Celsius and a chamber pressure between 100 and 300 mtorr. One illustrative process provides CF₄ at a flow rate of 400 sccm, N₂ at a flow rate of 120 sccm (i.e., a CF₄:N₂ flow ratio of about 10:3), Ar at a flow rate of 400 sccm, applies 1000 W of source power to the upper electrode, 1600 W of cathode bias power, maintains a wafer pedestal temperature of 20 degrees Celsius and a chamber pressure of 250 mtorr. Such a process provides etch selectivity for carbon doped silicon oxide (layer 208) over photoresist (mask 220) of at least 2.1:1, an etch rate of about 9500 Angstroms/min, 88 degrees sidewall slope, critical dimension (CD) bias of about 7.3 nm, and no micro-loading and striations.

During the period 122, the masking material (i.e., film 228) is removed from the via hole 228 and the photoresist mask 220 is stripped (FIG. 2J). In one illustrative embodiment, the period 122 uses either an oxygen-containing gas, e.g., oxygen (O₂), and the like or a nitrogen-containing gas, e.g., ammonia (NH₃), and the like. In one embodiment, the oxygen-containing gas further comprises a hydrogen (H₂) and/or an inert gas, such as at least one of argon (Ar), neon (Ne), nitrogen (N₂), and the like

In one illustrative embodiment, the planarizing film 228 comprising the organic material is etched by providing oxygen (O₂) at a flow rate of 300 to 1000, applying a source power between about 200 and 2000 W to the upper electrode, applying a cathode bias power between about 100 and 400 W, and maintaining a wafer pedestal temperature about −20 to 40 degrees Celsius at a chamber pressure between about 30 and 100 mtorr. One illustrative etch process uses O₂ at a flow rate of 500 sccm, applies 250 W of source power to the upper electrode, 300 W of cathode bias power and maintains a wafer temperature of 20 degrees Celsius at a chamber pressure of 30 mtorr.

During the period 124, step 116 etches and removes the second barrier layer 206 in the region 232 beneath the via hole 224 (FIG. 2K). In one embodiment, the period 122 uses a gas mixture comprising carbon tetrafluoride (CF₄), nitrogen (N₂), and one or more dilutant gases, such as argon (Ar) or carbon monoxide (CO).

In one illustrative embodiment, the second barrier layer 206 comprising the BLOK-II™ material is etched by providing carbon tetrafluoride (CF₄) at a flow rate of 20 to 100 sccm, oxygen (O₂) at a flow rate of 10 to 100 (i.e., a CF₄:0₂ flow ratio ranging from 1:5 to 10:1), argon (Ar) at a flow rate of 0 to 400, applying a source power between about 200 and 600 W to the upper electrode, applying a cathode bias power between about 200 and 400 W, and maintaining a wafer pedestal temperature about −20 to 40 degrees Celsius at a chamber pressure between about 5 and 50 mtorr. One illustrative etch process uses CF₄ at a flow rate of 40 sccm, O₂ at a flow rate of 20 sccm (i.e., a CF₄:0₂ flow ratio of about 2:1), Ar at a flow rate of 200 sccm, applies 400 W of source power to the upper electrode, 300 W of cathode bias power and maintains a wafer temperature of 20 degrees Celsius at a chamber pressure of 10 mtorr.

At step 126, the trench 218 and the via hole 224 are metallized (FIG. 2L). In one exemplary embodiment, step 126 uses a copper metallization process (e.g., an electroplating process) that forms a conductive layer 244. The electroplating process is well known in the art. During the process, the copper fills the via hole 224 and trench 218, as well as covers adjacent regions of the substrate 200 forming a sub-layer 246 (shown with a broken line) of excessive metal.

At step 128, the sub-layer 246 is removed and the copper layer is planarized (FIG. 2M). A planarization process (e.g., chemical-mechanical polishing (CMP) process) removes the excessive metal (i.e., sub-layer 246), as well as a portion of the cap layer 210. During removal of the sub-layer 246, the cap layer 210 protects the underlying low-k layer 208 from damage, such as erosion, cracking, peeling, and the like. After the planarization process, a remaining portion of the conductive layer 244 forms an embedded interconnect conductor 248, thereby completing the fabrication of the dual damascene interconnect structure.

At step 130, the sequence 100 ends.

FIG. 3 depicts a schematic diagram of the etch reactor 302 that illustratively may be used to practice portions of the invention. The etch reactor is generally used as a processing module of the CENTURA® semiconductor wafer processing system available from Applied Materials, Inc. of Santa Clara, Calif.

The reactor 302 generally comprises a process chamber 310 and a controller 340. The chamber 310 is a high vacuum vessel supplied with controlled throttle valve 327 and vacuum pump 336. The process chamber 310 further comprises a conductive body (wall) 330, a lid assembly 313, a wafer support pedestal 316, and a ceramic liner 331.

The lid assembly 313 generally comprises a showerhead 332 and an upper electrode 328. The showerhead 332 is mounted on the upper electrode 328 and may comprise several gas distribution zones such that various gases can be supplied to a reaction volume of the chamber 310 at specific flow rates. The upper electrode 328 is coupled to a very high frequency (VHF) source 318 through an impedance transformer 319 (e.g., a quarter-wavelength matching stub). The VHF source 318 is generally capable of producing up to 3000 Watts at a tunable frequency of above about 100 MHz.

The support pedestal 316 comprises an electrostatic chuck 326 for retaining a substrate 300. In operation, the substrate 300 is placed on the support pedestal (i.e., cathode) 316. The electrostatic chuck 326 is controlled using a DC power supply 320. The support pedestal 316 through a matching network 324 is coupled to a bias source 322. The bias source 322 is generally capable of producing up to 5000 W of radio-frequency (RF) power (i.e., cathode bias power) at a tunable frequency of about 50 kHz to 13.6 MHz. Optionally, the source 322 may be a source of DC or pulsed DC power.

The chamber wall 330 is generally formed from a metal (e.g., aluminum (Al), stainless steel, and the like) and coupled to an electrical ground terminal 334 of the reactor 302. The temperature of the chamber wall 330 is controlled using liquid-containing conduits (not shown) that are located in and around the wall.

The ceramic liner 331 facilitates in-situ cleaning of the process chamber 310. Using a plasma self-cleaning procedure, by-products and residue of etch processes may be removed from the liner 331 after one or more wafers have been processed in the chamber.

The process gas(es) are supplied from a gas panel 338 to the process chamber 310 through the showerhead 332. The pressure of a gas mixture 350 in the process chamber 310 may be controlled using the gas panel 338 and/or the throttle valve 327. The gas mixture 350 may be ignited into a plasma 352 in the reaction volume of the chamber 310 by applying power from the VHF source 318.

Temperature of the substrate 300 is controlled by stabilizing the temperature of the electrostatic chuck 326 and flowing a helium (He) gas from a gas source 348 into the channels that are formed by the back side of the substrate 300 and grooves (not shown) in a surface of the chuck. The electrostatic chuck 326 may be heated to a pre-determined steady-state temperature using a resistive heater (not shown) disposed in the body of the chuck. The helium gas facilitates a uniform heat transfer between the substrate 300 and electrostatic chuck 326. Using such thermal control, the substrate 300 may be maintained at a controlled temperature in a range from 10 to 500 degrees Celsius.

To facilitate control of the process chamber 310 as described above, the controller 340 may be one of any form of general-purpose computer processor that can be used in an industrial setting for controlling various chambers and sub-processors. The memory, or computer-readable medium, 342 of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like.

The inventive method is generally stored in the memory 342 as a software routine 304. The software routine 304 may also be stored and/or executed by a second CPU (not shown) that is remotely located from the hardware being controlled by the CPU 344. Some or all of the method steps of the present invention may also be performed in hardware. As such, the invention may be implemented in software and executed using a computer system, in hardware as, e.g., an application specific integrated circuit or other type of hardware implementation, or as a combination of software and hardware.

The invention may be practiced using other semiconductor wafer processing systems wherein the processing parameters may be adjusted to achieve acceptable characteristics by those skilled in the arts by utilizing the teachings disclosed herein without departing from the spirit of the invention. Although the forgoing discussion referred to fabrication of a dual damascene interconnect structure, fabrication of other devices and structures that are used in the integrated circuits can benefit from the invention.

While the foregoing is directed to the illustrative embodiment of the present invention, other and further embodiments of the invention may be devised without departing from the basic scope thereof, and the scope thereof is determined by the claims that follow.

What is claimed is:

1. A method of fabricating a structure on a substrate, comprising:
(a) providing a substrate having a first dielectric layer;
(b) forming a patterned mask over the first dielectric layer to define a feature to be etched;
(c) forming a plasma from a process gas by providing a plasma source power of between about 1000-2000 Watts and a cathode bias power of between about 800-1800 Watts to etch the feature into the first dielectric layer.

2. The method of claim 1, wherein the first dielectric layer comprises at least one of carbon doped silicon oxide, organic doped silicon glass, and fluorine doped silicon glass.

3. The method of claim 1, wherein the step (c) further comprises:
providing the plasma source power at a frequency greater than about 100 MHz.

4. The method of claim 3, wherein the frequency is about 160 MHz.

5. The method of claim 1, wherein the cathode bias power has a frequency in a range from about 50 kHz to 13.6 MHz.

6. The method of claim 1, wherein the process gas comprises carbon tetrafluoride (CF₄), nitrogen (N₂), and an inert diluent gas.

7. The method of claim 6, wherein the step (c) further comprises:
providing carbon tetrafluoride (CF₄) and nitrogen (N₂) at a flow ratio CF₄:N₂ in a range from 1:1.2 to 17:1.

8. The method of claim 6, wherein the step (c) further comprises:
providing carbon tetrafluoride (CF₄) at a flow rate of between about 100-500 sccm, and providing nitrogen (N₂) at a flow rate of between about 30-120 sccm.

9. The method of claim 8, wherein the step (c) further comprises:
providing argon (Ar) at a flow rate of between about 100-600 sccm.

10. The method of claim 1, wherein the step (c) further comprises:
maintaining a substrate pedestal temperature of between about 0-30 degrees Celsius.

11. The method of claim 1, wherein the step (c) further comprises:
maintaining a chamber pressure of between about 100-300 mtorr.

12. The method of claim 1, wherein the step (c) further comprises:
providing carbon tetrafluoride (CF₄) and nitrogen (N₂) at a flow ratio CF₄:N₂ in a range from 1:1.2 to 17:1;
providing argon (Ar) at a flow rate of between about 100-600 sccm;
maintaining a substrate pedestal temperature of between about 0-30 degrees Celsius; and
maintaining a chamber pressure of between about 100-300 mTorr.

13. The method of claim 1, wherein the step (c) provides a selectivity for the first dielectric layer to the mask of at least 2.1:1.

14. The method of claim 1, wherein the step (c) provides an etch rate of about 9500 Angstroms/minute.

15. The method of claim 1, further comprising:
(d) metallizing the feature.

16. A method of fabricating a structure on a substrate, comprising:
(a) providing a substrate having a first dielectric layer;
(b) forming a patterned mask over the first dielectric layer to define a feature to be etched;
(c) forming a plasma from a process gas comprising carbon tetrafluoride (CF₄), nitrogen (N₂), and an inert diluent gas by providing a plasma source power of between about 1000-2000 Watts and a cathode bias power of between about 800-1800 Watts while maintaining a substrate pedestal temperature of between about 0-30 degrees Celsius and a chamber pressure of between about 100-300 mTorr to etch the feature into the first dielectric layer.

17. A computer-readable medium containing software that, when executed by a computer, causes a processing system to fabricate an interconnect structure using a method, comprising:
(a) providing a substrate having a first dielectric layer;
(b) forming a patterned mask over the first dielectric layer to define a feature to be etched;
(c) forming a plasma from a process gas by providing a plasma source power of between about 1000-2000 Watts and a cathode bias power of between about 800-1800 Watts to etch the feature into the first dielectric layer.

18. The computer-readable medium of claim 18, wherein the step (c) further comprises:
providing carbon tetrafluoride (CF₄) and nitrogen (N₂) at a flow ratio CF₄:N₂ in a range from 1:1.2 to 17:1.

19. The computer-readable medium of claim 18, wherein the step (c) further comprises:
maintaining a substrate pedestal temperature of between about 0-30 degrees Celsius and a chamber pressure of between about 100-300 mtorr.

20. The computer-readable medium of claim 18, wherein the step (c) further comprises:
providing the plasma source power at a frequency greater than about 100 MHz.
